(19) United States
(12) Patent Application Publication
(10) Pub. No.: US 2023/0207701 A1
(43) Pub. Date: Jun. 29, 2023

(54) THIN-FILM TRANSISTOR AND DISPLAY APPARATUS

(71) Applicants: LG Display Co., Ltd., Seoul (KR); INDUSTRY-UNIVERSITY COOPERATION FOUNDATION HANYANG UNIVERSITY, Seoul (KR)

(72) Inventors: Jae Kyeong JEONG, Seoul (KR); Kwanghwan JI, Incheon (KR); Harkjin KIM, Incheon (KR); Minhoe CHO, Seoul (KR)

(21) Appl. No.: 18/055,726

(22) Filed: Nov. 15, 2022

(30) Foreign Application Priority Data
Dec. 28, 2021 (KR) 10-2021-0190131

(51) Int. Cl. H01L 29/786; H01L 27/12

(52) U.S. Cl. CPC H01L 29/7869; H01L 27/3262; H01L 27/1225

(57) ABSTRACT

A thin-film transistor includes a gate electrode, and an active layer insulated from the gate electrode by a gate insulating layer, and the active layer includes a quasi-superlattice structure with a first oxide semiconductor material and a second oxide semiconductor material having a larger bandgap than the first oxide semiconductor material alternately stacked at least twice. A display apparatus includes a thin-film transistor including an active layer of a quasi-superlattice structure for each pixel.

### CROSS-REFERENCE TO RELATED APPLICATION

This application claims priority from Korean Patent Application No. 10-2021-0190131 filed on Dec. 28, 2021 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a thin-film transistor and a display apparatus including the same, and more particularly, to an oxide semiconductor thin-film transistor with improved electrical characteristics and reliability, and a display apparatus including the same.

### Description of the Related Art

As society enters the full-fledged information, various display apparatuses that process and display a large amount of information have been developed. There are various types of flat panel display apparatuses, such as a liquid crystal display apparatus (LCD), an organic light-emitting display apparatus (OLED), and a quantum dot display apparatus.

The flat panel display apparatus includes a plurality of pixels and a driving circuit for displaying an image. Each pixel is provided with at least one thin-film transistor for controlling light emission, and the driving circuit also has a plurality of thin-film transistors.

As the thin-film transistor, an amorphous silicon thin-film transistor including an active layer made of amorphous silicon, a low-temperature polycrystalline silicon thin-film transistor including an active layer made of polycrystalline silicon, an oxide semiconductor thin-film transistor including an active layer made of an oxide semiconductor material, or the like is being used.

### BRIEF SUMMARY

Conventionally, when forming an active layer of an oxide semiconductor thin-film transistor, an RF sputtering scheme of depositing an oxide semiconductor thin-film on a substrate by tearing off a target made of an oxide semiconductor material (e.g., an indium-gallium zinc oxide (IGZO)) using plasma has been used.

Because the RF sputtering scheme uses a target of a fixed composition, there is a limit in a degree of freedom for characteristics of the thin-film transistor containing the oxide semiconductor material formed by such scheme. Moreover, in a sputtering scheme, it is difficult to finely change a thickness of the deposited oxide semiconductor thin-film at a nanometer (nm) level. A conventional oxide semiconductor thin-film transistor has poor electrical characteristics such as mobility of electric charges and poor reliability compared to a polycrystalline silicon thin-film transistor. Additional processes including a heat treatment process are beneficial to improve the electrical characteristics and the reliability of the oxide semiconductor thin-film transistor.

Accordingly, the inventors of the present disclosure invented a high-performance oxide semiconductor thin-film transistor by alternately depositing oxide semiconductor materials having different cation compositions using atomic layer deposition (ALD) to form an active layer having a quasi-superlattice structure.

One or more embodiments of the present disclosure provide an oxide semiconductor thin-film transistor with improved electrical characteristics and reliability, and a display apparatus including the same.

Other technical benefits and advantages of the present disclosure that are not mentioned may be understood based on following descriptions, and may be more clearly understood based on embodiments of the present disclosure. Further, it will be easily understood that the benefits and advantages of the present disclosure may be realized using means shown in the claims and combinations thereof.

A thin-film transistor according to an embodiment of the present disclosure includes a gate electrode, and an active layer insulated from the gate electrode by a gate insulating layer. The active layer may have a quasi-superlattice structure with a first oxide semiconductor material and a second oxide semiconductor material having a larger bandgap than the first oxide semiconductor material alternately stacked at least twice.

A display apparatus according to an embodiment of the present disclosure includes a plurality of pixels, and each thin-film transistor disposed in each of the plurality of pixels. The thin-film transistor may include a gate electrode, and an active layer insulated from the gate electrode by a gate insulating layer, and the active layer may have a quasi-superlattice structure with a first oxide semiconductor material and a second oxide semiconductor material having a larger bandgap than the first oxide semiconductor material alternately stacked at least twice.

Specific details of other embodiments are included in the detailed description and the drawings.

According to an embodiment of the present disclosure, by having the active layer with the quasi-superlattice structure based on indium-gallium oxide or indium-zinc oxide, an oxide semiconductor thin-film transistor capable of having a performance comparable to that of a low-temperature polycrystalline silicon thin-film transistor may be provided.

According to an embodiment of the present disclosure, by having the active layer with the quasi-superlattice structure based on indium-gallium oxide or indium-zinc oxide, an oxide semiconductor thin-film transistor with improved reliability may be provided.

According to an embodiment of the present disclosure, by having the active layer with the quasi-superlattice structure based on indium-gallium oxide or indium-zinc oxide, a high-performance and ultra-power-saving oxide semiconductor thin-film transistor having a driving voltage equal to or lower than 1.5 V may be provided.

According to an embodiment of the present disclosure, by disposing a thin film transistor including an oxide semiconductor layer having a quasi-superlattice structure for each pixel, a high-quality display device having low power consumption and excellent driving characteristics may be provided.

Effects of the present disclosure are not limited to the above-mentioned effects, and other effects as not mentioned will be clearly understood by those skilled in the art from following descriptions.

### BRIEF DESCRIPTION OF THE SEVERAL VIEWS OF THE DRAWINGS

FIG. 1 is a cross-sectional view showing a thin-film transistor according to an embodiment of the present disclosure.

FIG. 2 shows an energy band structure of an active layer of a quasi-superlattice structure.

FIG. 3 shows electrical characteristics of a thin-film transistor having an indium-gallium oxide (IGO)-based active layer according to an embodiment of the present disclosure.

FIG. 4 shows electrical characteristics of a thin-film transistor having an indium-zinc oxide (IZO)-based active layer according to an embodiment of the present disclosure.

FIG. 5 shows an energy band structure of an active layer with an IGO-based quasi-superlattice structure.

FIG. 6 shows an energy band structure of an active layer having an IZO-based quasi-superlattice structure.

FIG. 7 shows a C-V analysis result and a carrier concentration (N_{CV}) depth profile of an oxide semiconductor layer having a quasi-superlattice structure.

FIG. 8 shows a reliability evaluation result of a thin-film transistor according to embodiments of the present disclosure.

FIG. 9 is a plan view showing a structure of one pixel in an organic light-emitting display apparatus according to an embodiment of the present disclosure.

FIG. 10 is a cross-sectional view showing a structure of an organic light-emitting display apparatus cut along a line I-I′ in FIG. 9.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc., disclosed in the drawings for describing the embodiments of the present disclosure are examples, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is a separate explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a thin-film transistor and a display apparatus according to an embodiment of the present disclosure will be described in detail with reference to the accompanying drawings.

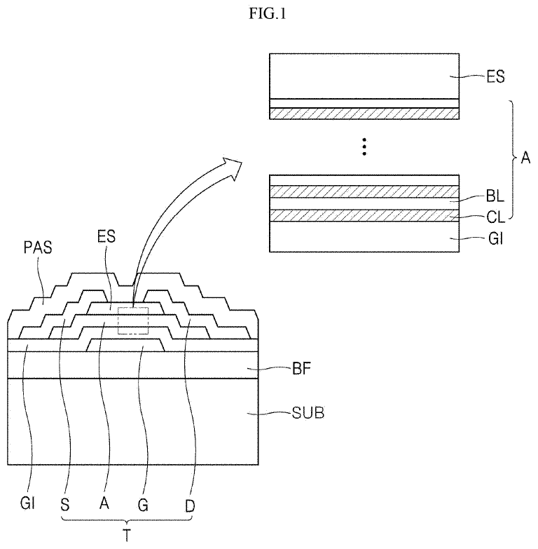

FIG. 1 is a cross-sectional view showing a thin-film transistor according to an embodiment of the present disclosure.

Referring to FIG. 1, a thin-film transistor according to an embodiment of the present disclosure includes a gate electrode G, an active layer A, a source electrode S, and a drain electrode D disposed on a substrate SUB.

A buffer layer BUF may be disposed on an entirety of a surface of the substrate SUB. In some cases, the buffer layer BUF may be omitted. Alternatively, the buffer layer BUF may have a structure in which a plurality of thin-film layers are stacked.

The gate electrode G may be disposed on the buffer layer BUF. A gate insulating layer GI for covering entirety of the surface of the substrate SUB may be disposed on the gate electrode G. The gate insulating layer GI may contain a silicon oxide, an aluminum oxide, a hafnium oxide, and the like. The gate insulating layer GI may have a multi-layer structure in which at least two materials among the above-described oxides are stacked.

The active layer A overlapping the gate electrode G may be disposed on the gate insulating layer GI. The active layer A may have a quasi-superlattice structure in which a confinement layer CL and a barrier layer BL are alternately stacked at least twice. For example, the confinement layer CL and the barrier layer BL in the active layer A may be alternately stacked twice, alternately stacked three times, alternately stacked four times, or alternately stacked five times. The confinement layer CL and the barrier layer BL may be formed by atomic layer deposition (ALD).

The confinement layer CL may be made of a first oxide semiconductor material, and the barrier layer BL may be made of a second oxide semiconductor material having a larger bandgap than the first oxide semiconductor material. The confinement layer CL may be made of the first oxide semiconductor material, and the barrier layer BL may be made of the second oxide semiconductor material having a smaller work function than the first oxide semiconductor material. For example, the confinement layer CL as, for example, a metal oxide having a thickness in a range from 2 nm to 5 nm (2 nm or more and 5 nm or less), may contain an indium-zinc oxide (IZO) or an indium-gallium oxide (IGO). For example, the barrier layer BL as, for example, a metal oxide having a thickness in a range from 2 nm to 5 nm (2 nm or more and 5 nm or less), may contain a gallium oxide. The thickness of the confinement layer CL may be the same as the thickness of the barrier layer BL. However, the present disclosure may not be limited thereto, and the thickness of the confinement layer CL may be different from the thickness of the barrier layer BL.

The lowermost confinement layer CL may be in contact with the gate insulating layer GI.

In the indium-zinc oxide (IZO) constituting the confinement layer CL, a content of indium may be greater than that of zinc. In order to change a band gap and a work function of the confinement layer CL, the content of indium and the content of zinc may be adjusted. For example, a ratio of the content of indium to the content of zinc may be 75 to 25.

Further, in the indium-gallium oxide (IGO) constituting the confinement layer CL, a content of indium may be greater than that of gallium. In order to change the band gap and the work function of the confinement layer CL, the content of indium and the content of gallium may be adjusted. For example, a ratio of the content of indium to the content of gallium may be 84 to 16.

As the confinement layer CL and the barrier layer BL form the quasi-superlattice structure in the active layer A, multiple quantum well structures and multiple channels may be formed in the active layer A. Carriers may be constrained in the confinement layer CL by the multiple quantum well structures, so that a system similar to a two-dimensional electron gas may be formed. Accordingly, the confinement layer CL may be provided as a channel.

A source electrode S and a drain electrode D are in contact with each other on the active layer A. The source electrode S and the drain electrode D are separated from each other by a certain distance. That is, the source electrode S is in contact with one side of the active layer A and the drain electrode D is in contact with the other side of the active layer A.

An etch stop layer ES may be further disposed on the active layer A. The etch stop layer ES is disposed on a central area of the active layer A, and the source electrode S and the drain electrode D are spaced apart from each other while respectively covering portions of the etch stop layer ES. The etch stop layer ES may protect the active layer A from an etchant flowing through the spaced portion between the source electrode S and the drain electrode D.

A protective film PAS for covering the thin-film transistor T may be disposed on the substrate.

According to an embodiment of the present disclosure, by having the active layer with the quasi-superlattice structure based on indium-gallium oxide or indium-zinc oxide, an oxide semiconductor thin-film transistor capable of having a performance comparable to that of a low-temperature polycrystalline silicon thin-film transistor may be provided.

Moreover, according to an embodiment of the present disclosure, by having the active layer with the quasi-superlattice structure based on indium-gallium oxide or indium-zinc oxide, an oxide semiconductor thin-film transistor with improved reliability may be provided.

Moreover, according to an embodiment of the present disclosure, by having the active layer with the quasi-superlattice structure based on indium-gallium oxide or indium-zinc oxide, a high-performance and ultra-power-saving oxide semiconductor thin-film transistor having a driving voltage equal to or lower than 1.5 V may be provided.

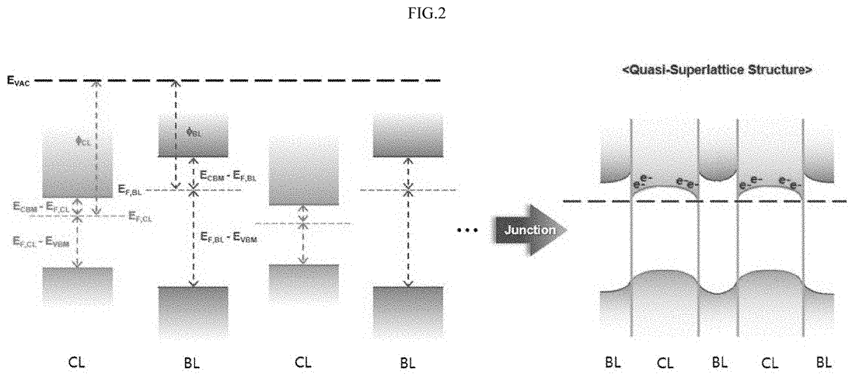

FIG. 2 shows an energy band structure of an active layer of a quasi-superlattice structure.

Referring to FIG. 2, the confinement layer CL has a smaller bandgap and a larger work function (Φ_{L}) than the barrier layer BL, and the barrier layer BL has a larger bandgap and a smaller work function (φ_{BL}) than the confinement layer CL. When the confinement layer CL and the barrier layer BL are made of the oxide semiconductor material, the confinement layer CL and the barrier layer BL having different band gaps and work functions may be alternately formed by controlling a composition of cations. For example, the confinement layer CL may be the indium-zinc oxide (IZO) or the indium-gallium oxide (IGO), and the barrier layer BL may be the gallium oxide.

When the confinement layer CL and the barrier layer BL are brought in contact, electrons move from the barrier layer BL to the confinement layer CL such that a Fermi level (E_{F, CL}) of the confinement layer CL and a Fermi level (E_{F, BL}) of the barrier layer BL become the same. Accordingly, band bending occurs in the barrier layer BL and the confinement layer CL as much as a difference between the work function (Φ_{L}) of the confinement layer CL and the work function (Φ_{BL}) of the barrier layer BL.

When the confinement layers CL and the barrier layers BL of several nm levels are alternately stacked to form the quasi-superlattice structure, the multiple quantum well structures and the multiple channels may be formed.

Previously, in FIG. 1, a thin-film transistor having a bottom gate structure has been described.

The active layer A having the structure in which the confinement layer CL and the barrier layer BL are alternately stacked at least twice as described above may be applied to a thin-film transistor having a top gate structure.

In the top gate structure, the active layer A may be disposed on the substrate first. The buffer layer may be interposed between the substrate and the active layer A. Moreover, the gate insulating layer may be disposed on the active layer A, and a gate electrode overlapping the active layer A may be disposed on the gate insulating layer. A protective insulating layer may be disposed on the gate electrode and the active layer A, and the source electrode and the drain electrode may extend through the protective insulating layer and the gate insulating layer to be respectively in contact with the both sides of the active layer A. The barrier layer BL and the confinement layer CL may be alternately stacked at least twice in an order in which the barrier layer BL is first disposed on the substrate and then the confinement layer CL is disposed on the barrier layer BL. The confinement layer CL may be disposed on the uppermost portion, and the uppermost confinement layer CL may be in contact with the gate insulating layer. Further, optionally, a light blocking layer may be further disposed only in a required portion between the buffer layer and the substrate. The light blocking layer may prevent external light from being introduced into the active layer of the thin-film transistor disposed thereon.

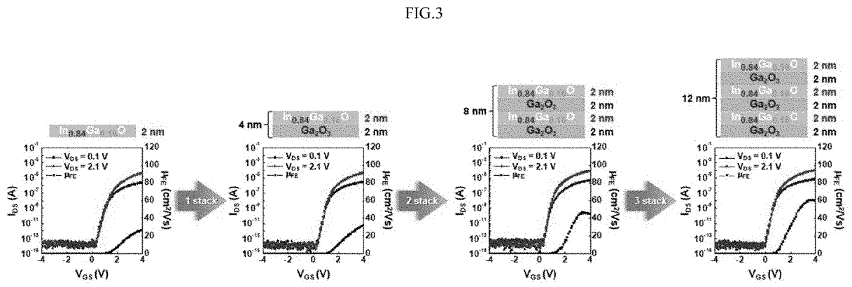

FIG. 3 shows electrical characteristics of a thin-film transistor having an indium-gallium oxide (IGO)-based active layer according to an embodiment of the present disclosure.

Electrical characteristics of thin-film transistors having active layers of various structures including at least one indium-gallium oxide thin-film were evaluated. The evaluation result is shown in FIG. 3. Channel widths of the thin-film transistors used in the evaluation of the electrical characteristics shown in FIG. 3 are 40 μm and channel lengths of the thin-film transistors are 20 m. The gate insulating layer of the thin-film transistors used in the evaluation of the electrical characteristics has a structure in which the aluminum oxide (5 nm) and the hafnium oxide (45 nm) are stacked. The active layers of the thin-film transistors used in the evaluation of the electrical characteristics respectively has a single layer made of In_{0.84}Ga_{0.16}O (total thickness 2 nm), a quasi-superlattice structure in which In_{0.84}Ga_{0.16}O (2 nm)/Ga₂O₃ (2 nm) are stacked once (total thickness 4 nm), a quasi-superlattice structure in which In_{0.84}Ga_{0.16}O (2 nm)/Ga₂O₃ (2 nm) are stacked twice (total thickness 8 nm), and a quasi-superlattice structure in which In_{0.84}Ga_{0.16}O (2 nm)/Ga₂O₃ (2 nm) are stacked three times (total thickness 12 nm). An In_{0.84}Ga_{0.16}O thin-film and a Ga₂O₃ thin-film of the active layer were formed by the atomic layer deposition (ALD). Post-deposition annealing (PDA) was performed at 400° C. in air.

The evaluation results of the electrical characteristics of the thin-films are summarized in Table 1 below.

TABLE 1

| Cation | | In_{0.84}Ga_{0.16}O/Ga₂O₃ | In_{0.84}Ga_{0.16}O/Ga₂O₃ | In_{0.84}Ga_{0.16}O/Ga₂O₃ |
|---|---|---|---|---|
| composition | In_{0.84}Ga_{0.16}O | stacked once | stacked twice | stacked three times |
| μ_{FE}[cm²/V s] | 26.5 | 32.3 | 46.2 | 60.4 |
| V_{TH}[V] | 1.36 | 1.21 | 1.04 | 0.85 |
| SS[V/dec] | 0.18 | 0.16 | 0.14 | 0.14 |
| I_{ON/OFF} | ~3.3 × 10⁹ | ~3.8 × 10⁹ | ~5.0 × 10⁹ | ~6.3 × 10⁹ |

Compared to the thin-film transistor having the active layer of the single layer of In_{0.84}Ga_{0.16}O, electrical characteristics of the thin-film transistors having the active layers of the quasi-superlattice structures in which In_{0.84}Ga_{0.16}O (2 nm) and Ga₂O₃ (2 nm) are stacked were better. As the number of stacks of In_{0.84}Ga_{0.16}O (2 nm) and Ga₂O₃ (2 nm) increases, the electrical characteristics of the thin-film transistor were further improved. Specifically, as the structure of the active layer is changed from the single layer to the quasi-superlattice structure in which In_{0.84}Ga_{0.16}O (2 nm)/Ga₂O₃ (2 nm) are stacked three times, a field effect mobility (E_{E}) increased from 26.5 to 60.4 and a threshold voltage V_{TH} decreased from 1.36V to 0.85V. Moreover, as the structure of the active layer is changed from the single layer to the quasi-superlattice structure in which In_{0.84}Ga_{0.16}O (2 nm)/Ga₂O₃ (2 nm) are stacked three times, a subthreshold swing (SS) decreased from 0.18 to 0.14 and an on/off current ratio increased from ˜3.3×10⁹ to ˜6.3×10⁹. Such improvement of the electrical characteristics of the thin-film transistor is made because of the formation of the two-dimensional electron gas and the multiple channels resulted from the introduction of the quasi-superlattice structure.

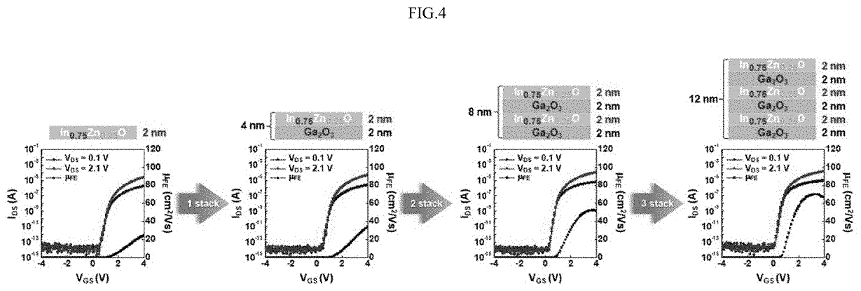

FIG. 4 shows electrical characteristics of a thin-film transistor having an indium-zinc oxide (IZO)-based active layer according to an embodiment of the present disclosure.

Electrical characteristics of thin-film transistors having active layers of various structures including at least one indium-zinc oxide thin-film were evaluated. The evaluation result is shown in FIG. 4. Channel widths of the thin-film transistors used in the evaluation of the electrical characteristics shown in FIG. 4 are 40 m and channel lengths of the thin-film transistors are 20 m. The gate insulating layer of the thin-film transistors used in the evaluation of the electrical characteristics has a structure in which the aluminum oxide (5 nm) and the hafnium oxide (45 nm) are stacked. The active layers of the thin-film transistors used in the evaluation of the electrical characteristics respectively has a single layer made of In_{0.75}Zn_{0.25}O (total thickness 2 nm), a quasi-superlattice structure in which In_{0.75}Zn_{0.25}O (2 nm)/Ga₂O₃ (2 nm) are stacked once (total thickness 4 nm), a quasi-superlattice structure in which In_{0.75}Zn_{0.25}O (2 nm)/Ga₂O₃ (2 nm) are stacked twice (total thickness 8 nm), and a quasi-superlattice structure in which In_{0.75}Zn_{0.25}O (2 nm)/Ga₂O₃ (2 nm) are stacked three times (total thickness 12 nm). An In_{0.75}Zn_{0.25}O thin-film and a Ga₂O₃ thin-film of the active layer were formed by the atomic layer deposition (ALD). The post-deposition annealing (PDA) was performed at 400° C. in air.

The evaluation results of the electrical characteristics of the thin-films are summarized in Table 2 below.

TABLE 2

| Cation | | In_{0.75}Zn_{0.25}O/Ga₂O₃ | In_{0.75}Zn_{0.25}O/Ga₂O₃ | In_{0.75}Zn_{0.25}O/Ga₂O₃ |
|---|---|---|---|---|
| composition | In_{0.75}Zn_{0.25}O | stacked once | stacked twice | stacked three times |
| μ_{FE}[cm²/V s] | 24.5 | 33.6 | 52.4 | 70.0 |
| V_{TH}[V] | 1.46 | 1.25 | 0.92 | 0.75 |
| SS[V/dec] | 0.16 | 0.15 | 0.13 | 0.12 |
| I_{ON/OFF} | ~3.5 × 10⁹ | ~4.0 × 10⁹ | ~5.5 × 10⁹ | ~7.0 × 10⁹ |

Compared to the thin-film transistor having the active layer of the single layer of In_{0.75}Zn_{0.25}O, electrical characteristics of the thin-film transistors having the active layers of the quasi-superlattice structures in which In_{0.75}Zn_{0.25}O (2 nm) and Ga₂O₃ (2 nm) are stacked were better. As the number of stacks of In_{0.75}Zn_{0.25}O (2 nm) and Ga₂O₃ (2 nm) increases, the electrical characteristics of the thin-film transistor were further improved. Specifically, as the structure of the active layer is changed from the single layer to the quasi-superlattice structure in which In_{0.75}Zn_{0.25}O (2 nm)/Ga₂O₃ (2 nm) are stacked three times, the field effect mobility (F_{E}) increased from 24.5 to 70.0 and the threshold voltage V_{TH} decreased from 1.46 V to 0.75 V. Moreover, as the structure of the active layer is changed from the single layer to the quasi-superlattice structure in which In_{0.75}Zn_{0.25}O (2 nm)/Ga₂O₃ (2 nm) are stacked three times, the subthreshold swing (SS) decreased from 0.16 to 0.12 and the on/off current ratio increased from ˜3.5×10⁹ to ˜7.0×10⁹. Such improvement of the electrical characteristics of the thin-film transistor is made because of the formation of the two-dimensional electron gas and the multiple channels resulted from the introduction of the quasi-superlattice structure.

Meanwhile, electrical characteristics of the thin-film transistor with the active layer of the indium-zinc oxide (IZO)-based quasi-superlattice structure, specifically, the active layer of the quasi-superlattice structure in which In_{0.75}Zn_{0.25}O (2 nm) and Ga₂O₃ (2 nm) are stacked were better than electrical characteristics of the thin-film transistor with the active layer of the indium-gallium oxide (IGO)-based quasi-superlattice structure, specifically, the active layer of the quasi-superlattice structure in which In_{0.84}Ga_{0.16}O (2 nm) and Ga₂O₃ (2 nm) are stacked.

Such difference in the electrical characteristics is based on a fact that, as will be described below, because a difference between a work function of In_{0.75}Zn_{0.25}O and a work function of Ga₂O₃ is larger than a difference between a work function of In_{0.84}Ga_{0.16}O and a work function of Ga₂O₃, a larger band bending of the barrier layer BL and the confinement layer CL occurs in a heterojunction of In_{0.75}Zn_{0.25}O and Ga₂O₃ compared to a heterojunction of In_{0.84}Ga_{0.16}O and Ga₂O₃.

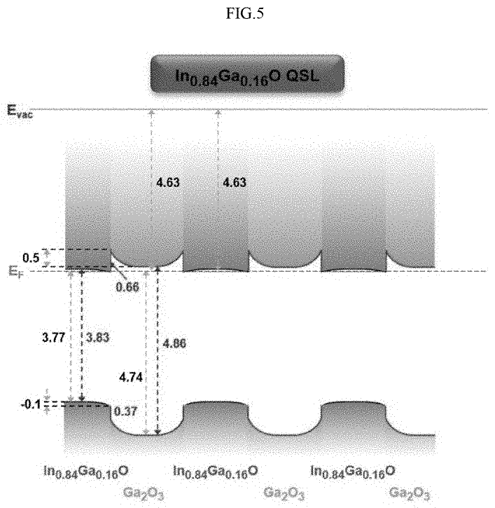

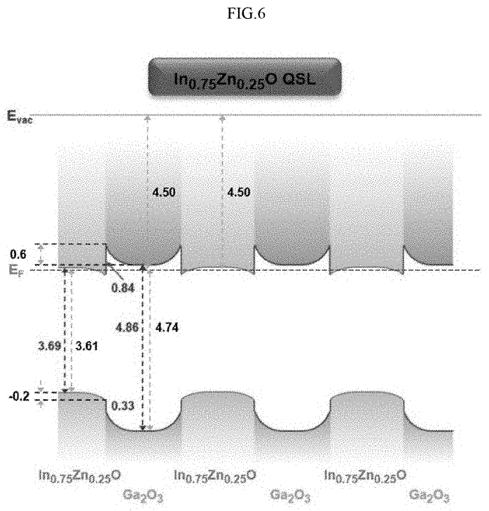

FIG. 5 shows an energy band structure of an active layer with an IGO-based quasi-superlattice structure, and FIG. 6 shows an energy band structure of an active layer having an IZO-based quasi-superlattice structure.

FIG. 5 shows an energy band diagram of the active layer having the quasi-superlattice structure in which, for example, the confinement layer CL made In_{0.84}Ga_{0.16}O and the barrier layer BL made of Ga₂O₃ are alternately stacked. Referring to FIG. 5, a band bending of the barrier layer BL is about 0.5 eV and a band bending of the confinement layer CL is about −0.1 eV.

FIG. 6 shows an energy band diagram of the active layer having the quasi-superlattice structure in which, for example, the confinement layer CL made of In_{0.75}Zn_{0.25}O and the barrier layer BL made of Ga₂O₃ are alternately stacked. Referring to FIG. 6, a band bending of the barrier layer BL is about 0.6 eV and a band bending of the confinement layer CL is about −0.2 eV.

Because the difference between the work function of In_{0.75}Zn_{0.25}O and the work function of Ga₂O₃ is larger than the difference between the work function of In_{0.84}Ga_{0.16}O and the work function of Ga₂O₃, the larger band bending of the barrier layer BL and the confinement layer CL occurs in the heterojunction of In_{0.75}Zn_{0.25}O and Ga₂O₃ compared to the heterojunction of In_{0.84}Ga_{0.16}O and Ga₂O₃.

Accordingly, a higher concentration of carriers may be confined in the confinement layer CL in the heterojunction of In_{0.75}Zn_{0.25}O and Ga₂O₃ compared to the heterojunction of In_{0.84}Ga_{0.16}O and Ga₂O₃.

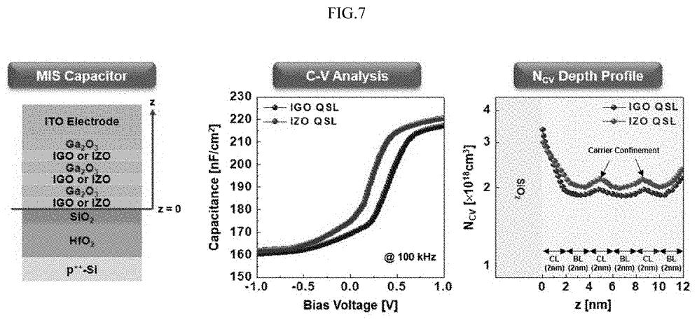

FIG. 7 shows a C-V analysis result and a carrier concentration (N_{CV}) depth profile of an oxide semiconductor layer having a quasi-superlattice structure.

A MIS capacitor structure as shown in FIG. 7 was formed for C-V analysis. A thickness of the gate insulating layer is 50 nm (SiO₂/HfO₂), a thickness of the confinement layer CL is 2 nm, a thickness of the barrier layer BL is 2 nm, and a quasi-superlattice structure was formed by alternately stacking the confinement layer and the barrier layer three times. In FIG. 7, IGO QSL means a quasi-superlattice structure in which In_{0.84}Ga_{0.16}O and Ga₂O₃ are alternately stacked three times, and IZO QSL means a quasi-superlattice structure in which In_{0.75}Zn_{0.25}O and Ga₂O₃ are alternately stacked three times.

As a result of the C-V analysis, it was identified that accumulation occurred at a bias voltage equal to or higher than 0.4V and depletion occurred at a bias voltage equal to or lower than OV.

Referring to the carrier concentration (N_{CV}) depth profile, when the IGO QSL or the IZO QSL was introduced, carrier confinement in 2nd and 3rd confinement layers CL was identified. Such constrained carriers may behave similarly to the two-dimensional electron gas.

In the case of IGO QSL, the carrier confinement occurred at z=4.8 nm (the 2nd confinement layer) and z=8.7 nm (the 3rd confinement layer). In the case of IZO QSL, the carrier confinement occurred at z=4.9 nm (the 2nd confinement layer) and 8.5 nm (the 3rd confinement layer).

The constrained carrier concentration was about 2.15×10¹⁸ cm⁻³ for the IZO QSL and was about 1.96×10¹⁸ cm⁻³ for the IGO QSL. A confinement level was about 1.4×10¹⁷ cm⁻³ for the IZO QSL and was about 0.9×10¹⁷ cm⁻³ for the IGO QSL. Both the constrained carrier concentration and the confinement level were higher for the IZO QSL than for the IGO QSL. This is because the larger band bending occurred in the IZO QSL compared to the IGO QSL.

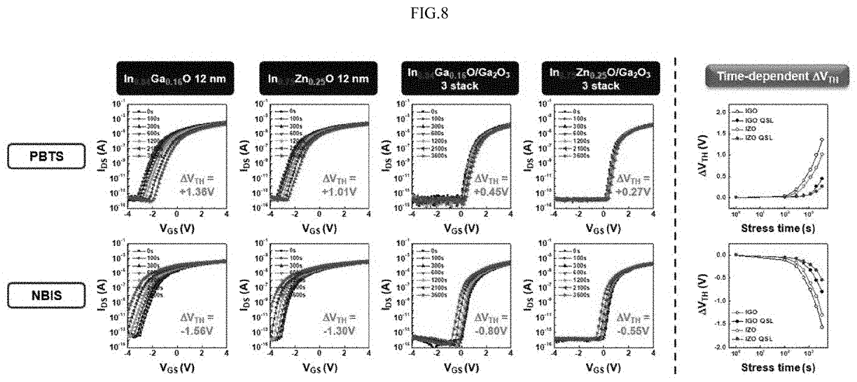

FIG. 8 shows a reliability evaluation result of a thin-film transistor according to embodiments of the present disclosure.

As shown in FIG. 8, positive bias temperature stress (PBTS) and negative bias illumination stress (NBIS) characteristics were evaluated for various thin-film transistors.

Stress conditions are as follows.

PBTS: V_{GS}=V_{TH}+10 V at 60° C. for 3,600 s

NBIS: V_{GS} V_{TH}−10 V for 3,600 s with green LED (0.066 mW/cm²)

Compared to reliability of the thin-film transistor with the active layer of the single layer of In_{0.84}Ga_{0.16}O, reliability of the thin-film transistor with the active layer of the quasi-superlattice structure in which In_{0.84}Ga_{0.16}O (2 nm) and Ga₂O₃ (2 nm) are stacked was better. Compared to reliability of the thin-film transistor with the active layer of the single layer of In_{0.75}Zn_{0.25}0, reliability of the thin-film transistor with the active layer of the quasi-superlattice structure in which In_{0.75}Zn_{0.25}O (2 nm) and Ga₂O₃ (2 nm) are stacked was better.

Moreover, the reliability of the thin-film transistor with the active layer of the quasi-superlattice structure in which In_{0.75}Zn_{0.25}O (2 nm) and Ga₂O₃ (2 nm) are alternately stacked three times alternately was better than the reliability of the thin-film transistor with the active layer of the quasi-superlattice structure in which In_{0.84}Ga_{0.16}O (2 nm) and Ga₂O₃ (2 nm) are alternately stacked three times.

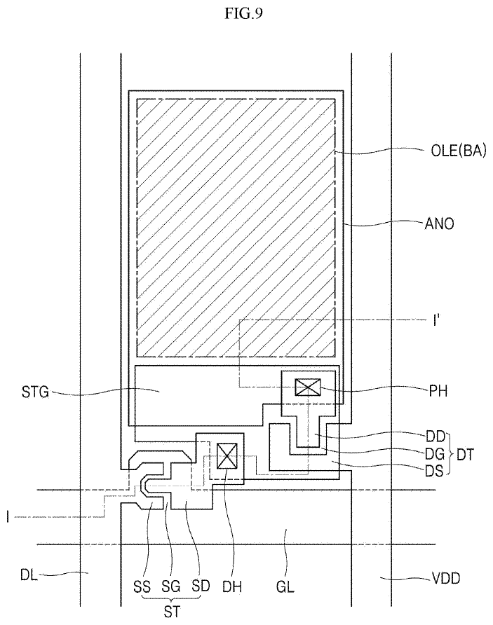

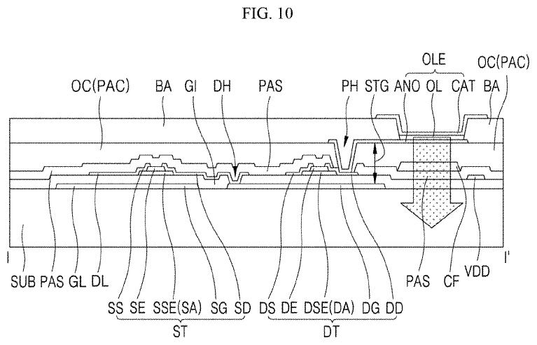

FIG. 9 is a plan view showing a structure of one pixel in an organic light-emitting display apparatus according to an embodiment of the present disclosure. FIG. 10 is a cross-sectional view showing a structure of an organic light-emitting display apparatus cut along a line I-I′ in FIG. 9.

Referring to FIGS. 9 and 10, an organic light-emitting display apparatus includes a switching thin-film transistor ST, a driving thin-film transistor DT connected to the switching thin-film transistor, and an organic light-emitting diode OLE connected to the driving thin-film transistor DT.

The switching thin-film transistor ST is disposed on the substrate SUB in a portion where a gate line GL and a data line DL overlap each other. The switching thin-film transistor ST performs a function of selecting a pixel by supplying a data voltage from the data line DL to a gate electrode DG of the driving thin-film transistor DT and a storage capacitance STG in response to a scan signal.

The switching thin-film transistor ST includes a gate electrode SG branching from the gate line GL, an active layer SA, a source electrode SS, and a drain electrode SD. In addition, the driving thin-film transistor DT drives the organic light-emitting diode OLE of the pixel selected by the switching thin-film transistor ST by adjusting a current flowing through the organic light-emitting diode OLE of the pixel based on the gate voltage.

The driving thin-film transistor DT includes a gate electrode DG connected to the drain electrode SD of the switching thin-film transistor ST, an active layer DA, a source electrode DS connected to a power voltage line VDD, and a drain electrode DD. The drain electrode DD of the driving thin-film transistor DT is connected to an anode electrode ANO of the organic light-emitting diode OLE. An organic light-emitting layer OL is interposed between the anode electrode ANO and a cathode electrode CAT. The cathode electrode CAT is connected to a base line.

The gate electrode SG of the switching thin-film transistor ST and the gate electrode DG of the driving thin-film transistor DT are disposed on the substrate SUB of the organic light-emitting display apparatus. Moreover, the gate insulating layer GI is disposed on the gate electrodes SG and DG. The active layers SA and DA are disposed on portions of the gate insulating layer GI respectively overlapping the gate electrodes SG and DG. Each of the source electrodes SS and DS and each of the drain electrodes SD and DD are disposed on each of the active layers SA and DA at a certain spacing. Each of etch stop layers SE and DE is disposed on a central area of each of the active layers SA and DA, and each of the source electrodes SS and DS and each of the drain electrodes SD and DD are respectively disposed on both sides of each of the etch stop layers SE and DE.

The drain electrode SD of the switching thin-film transistor ST is in contact with the gate electrode DG of the driving thin-film transistor DT via a drain contact hole DH extending through the gate insulating layer GI. A protective film PAS for covering the switching thin-film transistor ST and the driving thin-film transistor DT is stacked on the entirety of the surface of the substrate.

A color filter CF is disposed in a portion corresponding to an area of the anode electrode ANO. As such, the surface of the substrate on which the switching thin-film transistor ST, the driving thin-film transistor DT, and the color filter CF are disposed is not flat. Light may be uniformly emitted and evenly distributed only when the organic light-emitting layer OL is stacked on a flat surface. Therefore, for a purpose of planarizing the surface of the substrate, a planarization layer PAC or an overcoat layer OC is stacked on the entire surface of the substrate.

Moreover, the anode electrode ANO of the organic light-emitting diode OLE is disposed on the overcoat layer OC. Herein, the anode electrode ANO is connected to the drain electrode DD of the driving thin-film transistor DT via a pixel contact hole PH defined in the overcoat layer OC and the protective film PAS.

On the substrate on which the anode electrode ANO is disposed, in order to define the pixel area, a bank BA (or a bank pattern) is disposed on the area where the switching thin-film transistor ST, the driving thin-film transistor DT, and the various lines DL, GL, and VDD are disposed. The anode electrode ANO exposed by the bank BA becomes a light-emitting area. The organic light-emitting layer OL is stacked on the anode electrode ANO exposed by the bank BA. In addition, the cathode electrode CAT is stacked on the organic light-emitting layer OL. When the organic light-emitting layer OL is made of an organic material emitting white light, a color assigned to each pixel is realized by the color filter CF located below the organic light-emitting layer OL. The organic light-emitting display apparatus having the structure as shown in FIG. 10 becomes a bottom emission display apparatus that emits light in a downward direction.

The storage capacitance STG is disposed between the gate electrode DG and the anode electrode ANO of the driving thin-film transistor DT. The storage capacitance STG is connected to the driving thin-film transistor DT, so that a voltage applied to the gate electrode DG of the driving thin-film transistor DT by the switching thin-film transistor ST is stably maintained.

The thin-film transistor including the active layer composed of the oxide semiconductor layer of the quasi-superlattice structure according to an embodiment of the present disclosure may be applied to at least one of the switching thin-film transistor ST and the driving thin-film transistor DT.

Therefore, a high-quality organic light-emitting display apparatus having low power consumption and excellent driving characteristics may be implemented.

Further, although the organic light-emitting display apparatus was described as an example in FIGS. 9 and 10, the thin-film transistor including the active layer composed of the oxide semiconductor layer of the quasi-superlattice structure according to an embodiment of the present disclosure may be applied to the thin-film transistor disposed in each pixel of the liquid crystal display apparatus. Accordingly, the high-quality liquid crystal display apparatus having the low power consumption and the excellent driving characteristics may be implemented.

The thin-film transistor and the display apparatus according to embodiments of the present disclosure may be described as follows.

A thin-film transistor according to an embodiment of the present disclosure includes a gate electrode, and an active layer insulated from the gate electrode by a gate insulating layer, and the active layer has a quasi-superlattice structure with a first oxide semiconductor material and a second oxide semiconductor material having a larger bandgap than the first oxide semiconductor material alternately stacked at least twice.

According to an embodiment of the present disclosure, the first oxide semiconductor material may be an indium zinc oxide and the second oxide semiconductor material may be a gallium oxide.

According to an embodiment of the present disclosure, a content of indium may be greater than a content of zinc in the indium zinc oxide.

According to an embodiment of the present disclosure, a ratio of the content of indium to the content of zinc may be 75 to 25.

According to an embodiment of the present disclosure, the first oxide semiconductor material may be an indium gallium oxide and the second oxide semiconductor material may be a gallium oxide.

According to an embodiment of the present disclosure, a content of indium may be greater than a content of gallium in the indium gallium oxide.

According to an embodiment of the present disclosure, a ratio of the content of indium to the content of gallium may be 84 to 16.

According to an embodiment of the present disclosure, the first oxide semiconductor material may be in contact with the gate insulating layer.

According to an embodiment of the present disclosure, a thickness of the first oxide semiconductor material may be equal to a thickness of the second oxide semiconductor material.

According to an embodiment of the present disclosure, thicknesses of the first oxide semiconductor material and the second oxide semiconductor material may be in a range from 2 nm or more and 5 nm or less.

A display apparatus according to an embodiment of the present disclosure includes a plurality of pixels, and each thin-film transistor disposed in each of the plurality of pixels, the thin-film transistor includes a gate electrode, and an active layer insulated from the gate electrode by a gate insulating layer, and the active layer has a quasi-superlattice structure with a first oxide semiconductor material and a second oxide semiconductor material having a larger bandgap than the first oxide semiconductor material alternately stacked at least twice.

According to an embodiment of the present disclosure, the first oxide semiconductor material may be an indium zinc oxide or an indium gallium oxide and the second oxide semiconductor material may be a gallium oxide.

According to some embodiments of the present disclosure, a content of indium may be greater than a content of zinc or a content of gallium in the first oxide semiconductor material.

According to some embodiments of the present disclosure, the first oxide semiconductor material may be in contact with the gate insulating layer.

According to some embodiments of the present disclosure, a thickness of the first oxide semiconductor material may be equal to a thickness of the second oxide semiconductor material.

Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure. The scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin-film transistor comprising:
a gate electrode;
a gate insulating layer; and
an active layer insulated from the gate electrode by the gate insulating layer, the active layer including a quasi-superlattice structure with a first oxide semiconductor material and a second oxide semiconductor material alternately stacked at least twice, the second oxide semiconductor material having a larger bandgap than the first oxide semiconductor material.

2. The thin-film transistor of claim 1, wherein the first oxide semiconductor material includes an indium zinc oxide and the second oxide semiconductor material includes a gallium oxide.

3. The thin-film transistor of claim 2, wherein a content of indium is greater than a content of zinc in the indium zinc oxide.

4. The thin-film transistor of claim 3, wherein a ratio of the content of indium to the content of zinc is 75 to 25.

5. The thin-film transistor of claim 1, wherein the first oxide semiconductor material includes an indium gallium oxide and the second oxide semiconductor material includes a gallium oxide.

6. The thin-film transistor of claim 5, wherein a content of indium is greater than a content of gallium in the indium gallium oxide.

7. The thin-film transistor of claim 6, wherein a ratio of the content of indium to the content of gallium is 84 to 16.

8. The thin-film transistor of claim 1, wherein the first oxide semiconductor material is in contact with the gate insulating layer.

9. The thin-film transistor of claim 1, wherein a thickness of the first oxide semiconductor material corresponds to a thickness of the second oxide semiconductor material.

10. The thin-film transistor of claim 1, wherein thicknesses of the first oxide semiconductor material and the second oxide semiconductor material are in a range from 2 nm or more and 5 nm or less.

11. A display apparatus comprising:
a plurality of pixels; and
each thin-film transistor disposed in each of the plurality of pixels,
each thin-film transistor including:
a gate electrode;
a gate insulating layer; and
an active layer insulated from the gate electrode by the gate insulating layer,
the active layer including a quasi-superlattice structure with a first oxide semiconductor material and a second oxide semiconductor material alternately stacked at least twice, the second oxide semiconductor material having a larger bandgap than the first oxide semiconductor material.

12. The display apparatus of claim 11, wherein the first oxide semiconductor material includes an indium zinc oxide or an indium gallium oxide and the second oxide semiconductor material includes a gallium oxide.

13. The display apparatus of claim 12, wherein a content of indium is greater than a content of zinc or a content of gallium in the first oxide semiconductor material.

14. The display apparatus of claim 11, wherein the first oxide semiconductor material is in contact with the gate insulating layer.

15. The display apparatus of claim 11, wherein a thickness of the first oxide semiconductor material corresponds to a thickness of the second oxide semiconductor material.
